(19) United States
(12) Patent Application Publication
(10) Pub. No.: US 2005/0285522 A1
(43) Pub. Date: Dec. 29, 2005

(54) Electro-luminescent display device

(76) Inventors: Dong-Won Han, Sowon-si (KR); Eung-Jin Kim, Sowon-si (KR)

Correspondence Address: MCGUIREWOODS, LLP, 1750 TYSONS BLVD, SUITE 1800, MCLEAN, VA, 22102, US

(21) Appl. No.: 11/153,313

(22) Filed: Jun. 16, 2005

(30) Foreign Application Priority Data
Jun. 17, 2004 (KR) 10-2004-0045030

(51) Int. Cl. H05B 33/04

(52) U.S. Cl. 313/512; 313/503

(57) ABSTRACT

The present invention provides an electro-luminescent display device that includes a substrate having a display region. A pad may be formed on the substrate. A sealing portion comprise a sealing material may be disposed outside the display region. A sealing substrate may seal at least the display region in combination with the substrate via the sealing material. A concave portion may be formed in at least part of the substrate below the sealing portion.

### CROSS REFERENCE TO RELATED APPLICATION

This application claims priority to Korean Patent Application No. 10-2004-0045030, filed on Jun. 17, 2004, in the Korean Intellectual Property Office, the disclosure of which is herein incorporated by reference in its entirety.

### BACKGROUND OF THE INVENTION

1. Field of the Invention

The present invention relates to an electro-luminescent display device, and more particularly, to an electro-luminescent display device having a structure that extends the longevity of the electro-luminescent display device by more effectively sealing a display region.

2. Description of the Related Art

Flat panel display devices, such as liquid crystal display devices, organic electro-luminescent display devices, and inorganic electro-luminescent display devices, may be passive matrix (PM) flat panel display device or active matrix (AM) flat panel display devices depending on the type of driving method used. The PM flat panel display device has anodes arranged in columns and cathodes arranged in rows. A row driving circuit supplies a scanning signal to the cathode and drives only one row at a time. A column driving circuit drives one of the columns, thereby inputting a data signal to pixels. On the other hand, an AM flat panel display device controls a signal inputted to each pixel using a thin film transistor (TFT) and is suitable for processing a large number of signals. Thus, an AM flat panel display devices are widely used for displaying moving images.

An organic electro-luminescent display device has an organic luminescent layer, composed of an organic compound, disposed between an anode and a cathode. When a voltage difference is applied between the anode and the cathode, holes injected from the anode migrate via a hole transport layer to the organic luminescent layer and electrons are injected from the cathode via a electron transport layer, to the organic luminescent layer. In the organic luminescent layer, the holes and the electrons recombine to produce exitons. When the exitons drop from an excited state to ground state, fluorescent molecules in the organic luminescent layer emit light, thereby forming an image. Full color organic electro-luminescent display device include pixels emitting three different colors of light, such as red (R), green (G), and blue (B).

Japanese Patent Publication No. 2004-055365 discloses an electro-luminescent display device having a stress buffering layer that prevents a desiccant layer from damage caused by the difference between the thermal expansion coefficients of the desiccant layer and a sealing glass substrate.

Japanese Patent Publication No. 2002-299043 discloses a sealing structure of an organic electro-luminescent display device in which a substrate and a sealing member are bonded by a photocurable resin to seal an organic luminescent element. A glass sealing member is used so that the problems in the preparation which may occur when using a metallic sealing member are resolved.

However, in the conventional approaches referenced above, the substrate and the sealing member are simply bonded by a sealing material such as an adhesive. A considerable portion of the deterioration of the electro-luminescent display device due to the permeation of oxygen and moisture is caused by permeation through the interface between the adhesive, which is the sealing material, and the substrate or the sealing member. Thus, the foregoing publications do not address or solve these problems.

### SUMMARY OF THE INVENTION

The present invention provides an electroluminescent display device having a structure that extends the longevity of the electro-luminescent display device by providing a more effective seal.

An embodiment of the present invention provides an electro-luminescent display device including a substrate having a display region. A pad portion may be formed on the substrate. A sealing portion composed of a sealing material may be disposed outside the display region. A sealing substrate may seal at least the display region in combination with the substrate via the sealing material. A concave portion may be formed in at least part of the substrate below the sealing portion.

Another embodiment of the present invention provides an electro-luminescent display device including a substrate having a display region. A pad portion may be formed on the substrate. A sealing portion composed of a sealing material may be disposed outside the display region. A sealing substrate may seal at least the display region in combination with the substrate through the sealing material. One or more insulating layers may be formed on the substrate. A concave portion may be formed in at least part of the insulating layers below the sealing portion.

### BRIEF DESCRIPTION OF THE DRAWINGS

The above and other features and advantages of the present invention will become more apparent by describing in detail exemplary embodiments thereof with reference to the attached drawings.

FIG. 1A is a schematic perspective view of an organic electro-luminescent display device according to an embodiment of the present invention.

FIG. 1B is a schematic plan view of a pixel of the display device shown in FIG. 1A.

FIG. 1C is a schematic cross-sectional view taken along the line I-I of FIG. 1B.

FIG. 2A and FIG. 2B are schematic plan views of organic electro-luminescent display devices having a concave portion according to embodiments of the present invention.

FIG. 2C and FIG. 2D are cross-sectional views taken along the line II-II of FIG. 2B according to embodiments of the present invention.

FIG. 3A, FIG. 3B and FIG. 3C are schematic partial cross-sectional views of organic electro-luminescent display devices according to another embodiments of the present invention.

FIG. 4A, FIG. 4B and FIG. 4C are plan views illustrating a process of preparing an organic electro-luminescent display device having a sealing layer according to an embodiment of the present invention.

FIG. 4D is a schematic cross-sectional view taken along the line III-III of FIG. 4C.

FIG. 5A, FIG. 5B and FIG. 5C are schematic partial cross-sectional views of organic electro-luminescent display devices according to another embodiments of the present invention.

### DETAILED DESCRIPTION OF THE INVENTION

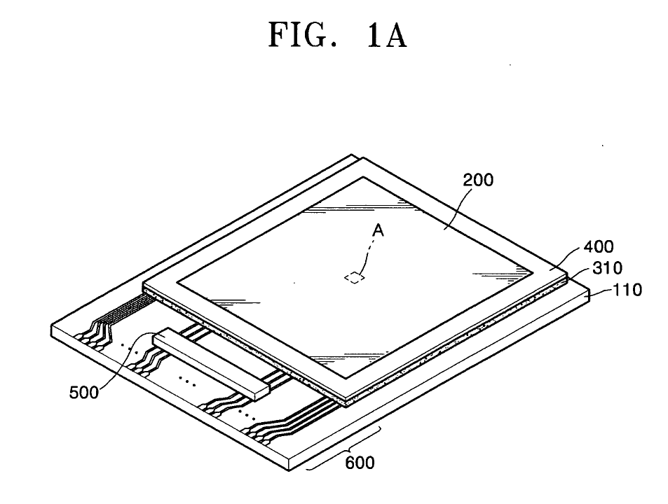

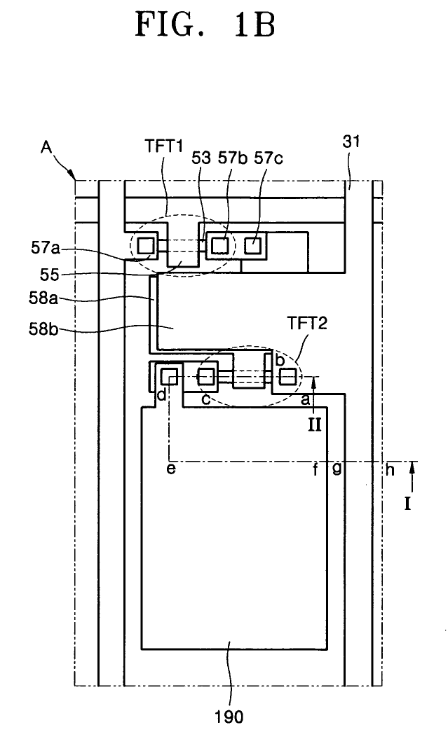

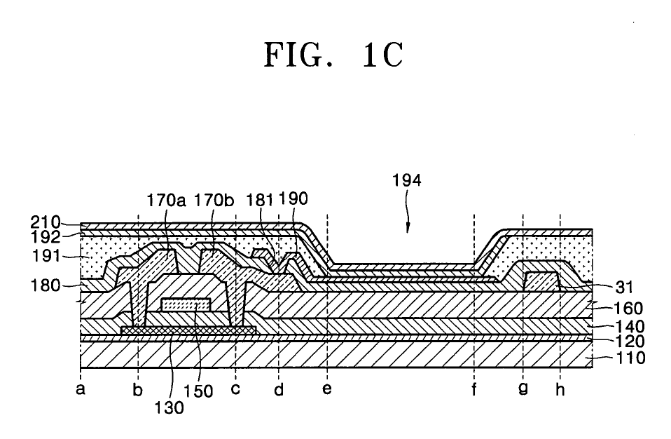

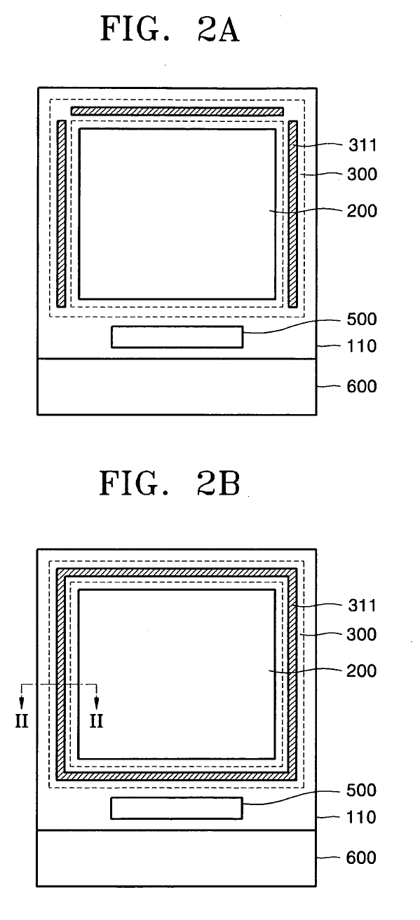

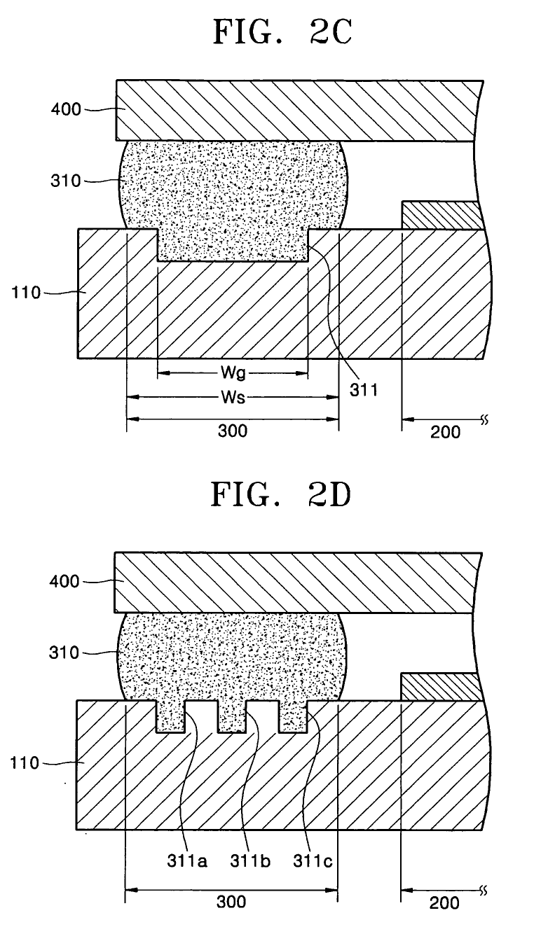

FIG. 1A is a schematic perspective view of an electro-luminescent display device manufactured according to the principles of the present invention. A display region 200 composed of one or more pixels is formed on a surface of a substrate 110 and a pad portion 600 composed of at least one terminal is disposed on the substrate 110 near an edge of the display region 200. A sealing portion 300 (FIG. 2A) for sealing at least the display region 200 in combination with the substrate 110 through a sealing material 310 is disposed between the display region 200 and the pad portion 600.

An electric element providing an electrical signal to the display region 200, for example, a vertical/horizontal driving circuit such as a scan driver/data driver which transmits a scan signal and/or a data signal to pixels of the display region 200 may be placed in a sealing region between the display region 200 and the sealing portion 300. The electric element may also be placed outside the sealing portion 300, like a horizontal driving circuit 500 illustrated in FIG. 1A. The vertical/horizontal driving circuit 500 may have various configurations. For example, the vertical/horizontal circuit 500 may have a COG form or comprise an external electric element through FPC, and the like.

FIG. 1B is an enlarged schematic diagram of a pixel A shown in FIG. 1A. Although a pixel having two top gate thin film transistors and one capacitor is illustrated in FIG. 1B, this is for illustrative purposes only, and is not intended to limit the scope of the invention.

A gate electrode 55 of a first thin film transistor TFT1 which determines whether the pixel is selected is extended from a scan line that supplies a scan signal. When an electrical signal such as the scan signal is applied to the scan line, a data signal inputted via a data line is transmitted from a source electrode 57a of the first thin film transistor TFT1 to a drain electrode 57b of the first thin film transistor TFT1 via a semiconductor active layer 53 of the first thin film transistor TFT1.

An elongated portion 57c of the drain electrode 57b of the first thin film transistor TFT1 is connected to an end of a first electrode 58a of the capacitor. The other end of the first electrode 58a of the capacitor forms a gate electrode 150 (FIG. 1C) of a second thin film transistor TFT2, which is a driving TFT, and a second electrode 58b of the capacitor is electrically connected to a driving line 31 communicating with a driving electric source supply line (not shown).

FIG. 1C is a partial cross-sectional view taken along the line I-I of FIG. 1B. A portion represented by the reference characters “a”, “b”, “c”, “d” and “e” of the line I-I illustrates a cross-section where a portion of the second thin film transistor TFT2 is disposed and a portion represented by the reference characters “e” and “f” illustrates a pixel opening 194. Also, a portion represented by the reference characters “g” and “h” illustrates a cross-section of the driving line 31. The second thin film transistor TFT2 includes a semiconductor active layer 130 formed on a buffer layer 120, which is formed on a surface of the substrate 110. The semiconductor active layer 130 may be an amorphous silicon layer or a polycrystalline silicon layer. Although it is not illustrated in FIG. 1C, the semiconductor active layer 130 consists of a source and drain region doped with N+ type or P+ type dopants and a channel region. The semiconductor active layer 130 may have various configurations and may be, for example, composed of an organic semiconductor.

A gate electrode 150 of the TFT2 is disposed on the semiconductor active layer 130 and may be composed of, for example, MoW, Al/Cu, etc., in view of a close adherence to an adjacent layer, a flat surface of a laminated layer, and processibility, but is not limited to these materials.

A gate insulating layer 140 may be interposed between the gate electrode 150 and the semiconductor active layer 130 so as to insulate them. An interlayer 160, which is an insulating layer, may be formed as a single layer or a multilayer on the gate electrode 150 and a gate insulating layer 140, and source and drain electrodes 170a and 170b of the TFT2 is formed thereon. The source and drain electrodes 170a and 170b may comprise a metal, such as MoW, and may be thermally treated later so as to achieve a smoother ohmic-contact with the semiconductor active layer 130.

A protective layer 180 that may comprise a passivation layer and/or a planarization layer and used for protection and/or planarization is formed on the source and drain electrodes 170a and 170b and a first electrode layer 190 is formed thereon. The first electrode layer 190 electrically communicates with the source and drain electrodes 170a and 170b through a via 181 formed in the protective layer 180. The first electrode layer 190 may have various forms. For example, in the case of a bottom emission display device, the first electrode layer 190 may be a transparent electrode composed of indium-tin-oxide (ITO), etc., and in the case of a top emission display device, the first electrode layer 190 may be a reflective electrode composed of Al/Ca and a transparent electrode composed of ITO, etc. Although the first electrode layer 190 may act as an anode, the present invention is not limited thereto and may have various configurations. For example, the first electrode layer may also act as a cathode.

Meanwhile, the protective layer 180 may have various configurations. For example, the protective layer 180 may comprise an inorganic or organic compound, and may be formed as a single layer or a double layer including an organic compound, such as benzocyclobutene (BCB) or acryl, on a SiNx layer.

A pixel definition layer 191 for defining a pixel except for the pixel opening 194 corresponding to the first electrode layer 190 may be formed on the protective layer 180. An organic electro-luminescent layer 192 including an emission layer is disposed on a surface of the first electrode layer 190 within the opening 194.

The organic electro-luminescent layer 192 may comprise a low molecular weight or high molecular weight organic membrane. The low molecular weight organic membrane may be a hole injection layer (HIL), a hole transport layer (HTL), an organic emission layer (EML), an electron transport layer (ETL), an electron injection layer (EIL), etc., laminated in a single or composite structure. The organic electro-luminescent layer 192 may comprise an organic materials such as copper phthalocyanine (CuPc), N,N′-di(naphthalene-1-yl)-N,N′-diphenyl-benzidine (NPB), or tris-8-hydroxyquinoline aluminum (Alq3). The low molecular weight organic membrane is formed through vacuum evaporation.

The high molecular weight organic membrane may be an HTL comprising PEDOT and an EML comprising a high molecular weight organic material, such as a poly-phenylenevinylene (PPV) based or polyfluorene based material. The high molecular weight organic membrane may be formed using a screen printing or inkjet printing method.

A second electrode layer 210, which is a cathode, is deposited on an entire surface of the organic electro-luminescent portion 192. The second electrode layer 210 is not limited to the entire surface-deposition form and may comprise Al/Ca, ITO, Mg—Ag, or the like according to an emission method of the display device. Also, the second electrode layer 210 may have a multi-layer structure and may further include a layer comprise an alkali metal or an alkali earth metal fluoride, such as LiF.

The organic electro-luminescent display device according to an embodiment of the present invention may have a concave portion in at least a portion corresponding to a sealing portion outside the display region on the substrate to prevent moisture and oxygen from permeating through the boundary surface of the sealing portion.

FIG. 2A and FIG. 2B are schematic plan views of an organic electro-luminescent display device having a concave portion according to embodiments of the present invention. Parts of the organic electro-luminescent display device, such as the sealing material 310 and the sealing substrate 400, are omitted for ease of explanation. A concave portion 311 is formed in at least a portion of the sealing portion 300 outside the display region 200 on the substrate 110. The concave portion 311 may be discontinuously formed outside the display region 200 as illustrated in FIG. 2A or may form a closed curve so as to better prevent oxygen and moisture from permeating into the sealing region as illustrated in FIG. 2B.

FIG. 2C and FIG. 2D are cross-sectional views taken along the line II-II of FIG. 2B and illustrate possible structures of the concave portion according to embodiments of the present invention. Referring to FIG. 2C, the concave portion 311 is formed in a surface of a substrate 110. The concave portion 311 may be formed by, for example, etching, laser etching, etc. the substrate 110.

The substrate 110 and the sealing substrate 400 are sealed by a sealing material 310 of the sealing portion 300. The sealing material 310 of the sealing portion 300 fills the concave portion 311. The width Wg of the concave portion 311 may be equal to the width Ws of the sealing portion 300. However, since most moisture and/or oxygen that enters the sealing region permeates through the interface between the substrate 110 and the sealing material 310, it is preferable to alter the direction of the route of moisture permeation/oxygen permeation, if possible, by setting the width Wg of the concave portion 311 to be less than the width Ws of the sealing portion 300 in which the sealing material 310 is disposed to better prevent moisture and/or oxygen from permeating.

According to another embodiment of the present invention, the concave portion may have a repeating recess-protrusion pattern. In FIG. 2D, the concave portion 311 consists of a plurality of recessed portions 311a, 311b and 311c. The recessed portions 311a, 311b and 311c may be differently sized, but are preferably equally sized for processing convenience. As the number of the recessed portions increases, the contact area between the sealing material 311 of the sealing portion 310 and the substrate 110 increases. However, there is a limit to the minimum width of the sealing portion 310. An excessive reduction in the width of the recessed portions 311a, 311b and 311c may result in insufficient filling of the recessed portions 311a, 311b and 311c with the sealing material due to gas contained in the recessed portions 311a, 311b and 311c or the viscosity of the sealing material, thereby not forming an effective sealing structure. The concave portion 311 may be disposed between the display region 200 and the pad portion 600 (FIG. 2B) and a failure may occur due to a disconnection that may be caused when wiring electrically communicating with the display region pass through the concave portion 311. Considering these possibilities, the concave portion 311 should have proper width and depth.

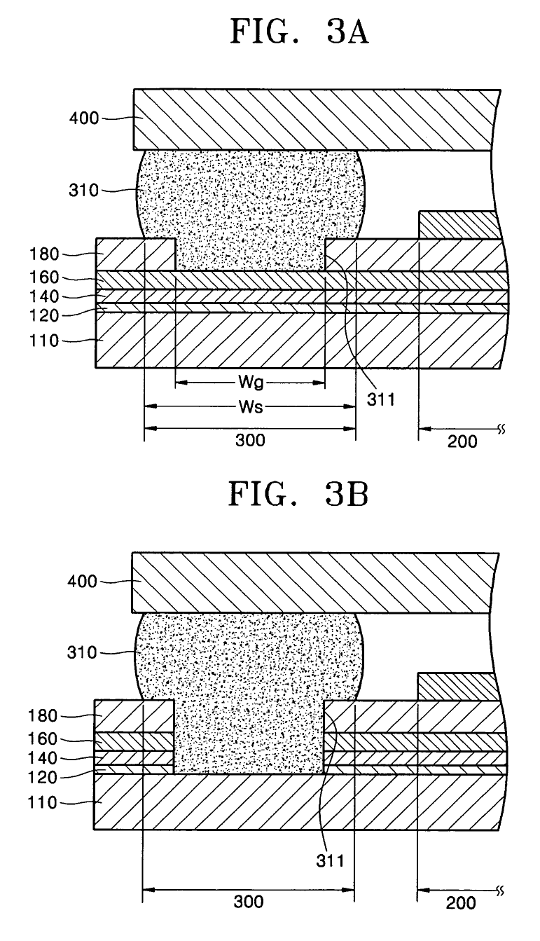

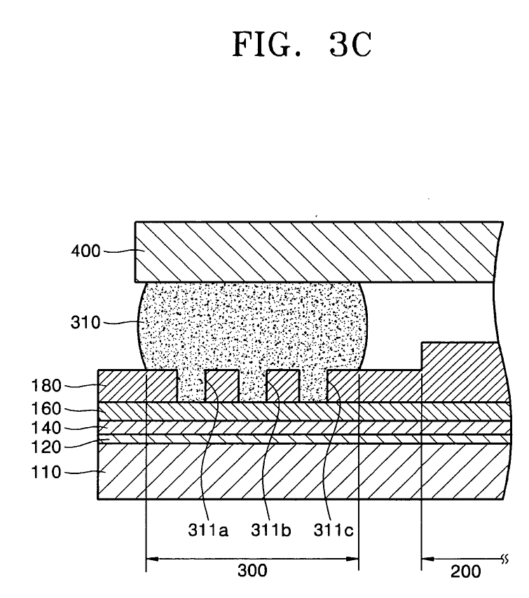

According to another embodiment of the present invention, the concave portion 311 formed on the substrate may be included in at least one insulating layer formed on a surface of the substrate. Referring to FIG. 3A, a buffer layer 120 of a TFT (FIG. 1C) extends to the sealing portion 300 on a surface of the substrate 110. A gate insulating layer 140 for insulating a semiconductor active layer 130 from a gate electrode 150 is formed on a surface of the buffering layer 120. Also, an interlayer 160 for insulating the gate electrode 150 and a source/drain electrode 170 may be disposed on a surface of the gate insulating layer 140 and a protective layer 180 is disposed thereon.

The concave portion 311 may extend through only the protective layer 180 as illustrated in FIG. 3A or may extend through the entire lower insulating layer as illustrated in FIG. 3B. Similarly to the previous embodiment, in the present embodiment, the width Wg of the concave portion 311 may be less than the width Ws of the sealing portion 300 in which the sealing material 310 is disposed.

The concave portion 311 may have a repeating recess-protrusion form. Referring to FIG. 3C, the concave portion 311 with the repeating recess-protrusion form includes a plurality of recessed portions 311a, 311b and 311c. The sizes of the recessed portions may be different, but are preferably equal in view of processing convenience. Although the concave portion 311 shown in FIG. 3C consists of three recessed portions 311a, 311b and 311c, the number of the recessed portions is not limited thereto. Similarly to the previous embodiments, the number and the width of the recessed portions can be properly selected according to a design specification of the organic electro-luminescent display device.

Also, the concave portion may be selectively formed in at least a part of one or more insulating layers formed in a position corresponding to the sealing portion on a surface of the substrate. In other words, the concave portion 311 may be selectively formed in a position corresponding to the sealing portion 300 in one or more insulating layers 140, 160 of insulating layers 120, 140, 160, 180 formed on a surface of the substrate 110 as illustrated in FIG. 3C. However, similar to FIG. 3A, the width Wg of the concave portion 311 is less than the width Ws of the sealing portion 300.

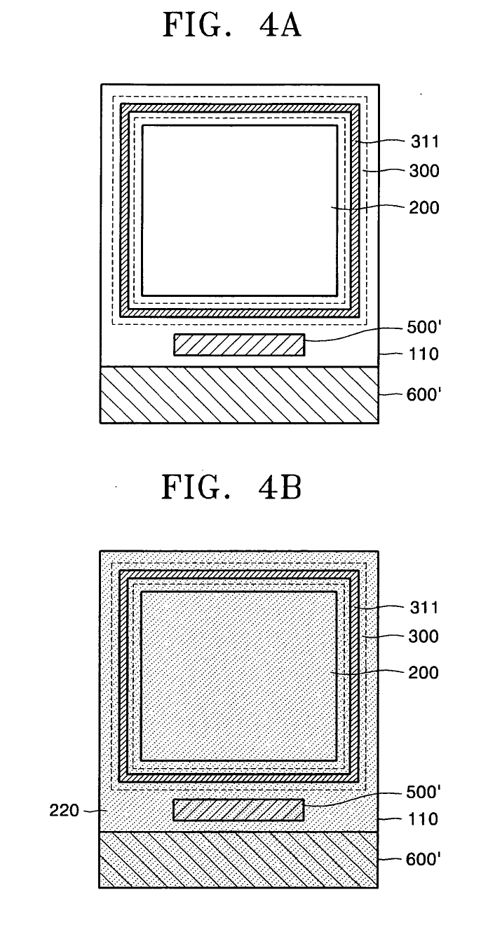

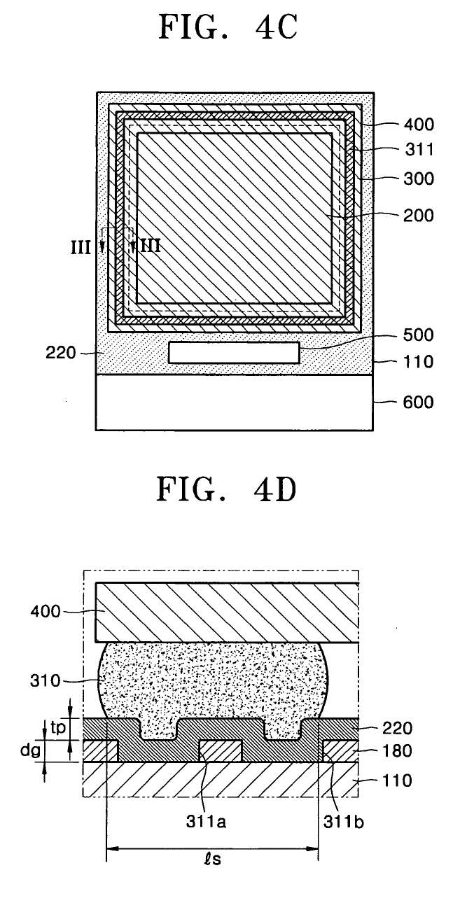

The organic electro-luminescent display device according to the present invention may further include a sealing layer on a surface of the display region to ensure the sealing of the display region. FIG. 4A, FIG. 4B and FIG. 4C are plan views illustrating a method of forming a sealing layer. First, referring to FIG. 4A, shadow layers 500′, 600′ are formed in a portion where a vertical/horizontal driving circuit 500 and a pad portion 600 will be placed on a surface of the substrate 110. The shadow layers 500′, 600′ may comprise an attachable tape. Alternatively, when the display region 200 includes an organic electro-luminescent portion comprise an EML and one or more organic compound layers, the organic compound layers of the organic electro-luminescent portion may be used as the shadow layers 500′, 600′. Then, referring to FIG. 4B, a sealing layer 220 is formed on the entire surface of the resultant product including the display region 200 and shadow layers 500′, 600′. The sealing layer 220 may be formed by depositing an insulating material such as SiO₂ or SiNx. Referring to FIG. 4C, after forming the sealing layer 220 a sealing material 310 is applied to the sealing portion 300, thereby joining the sealing substrate 400 and the substrate 110. Then, the shadow layers 500′, 600′ are removed and a cleaning process is performed to expose a portion on which the vertical/horizontal driving circuit portion 500 will be placed and a portion on which the pad portion 600 will be placed. For example, the horizontal driving circuit 500 may be placed a COG method. The sealing layer may be formed through various methods besides the above method.

FIG. 4D schematically illustrates a partial cross-section taken along the line III-III of FIG. 4C. Referring to FIG. 4D, a sealing layer 220 covering the display region 200 is interposed between the sealing material 310 and the concave portion 311 formed in the protective layer 180. With this structure, the display region 200 is better sealed since there is no portion contacting the sealing region.

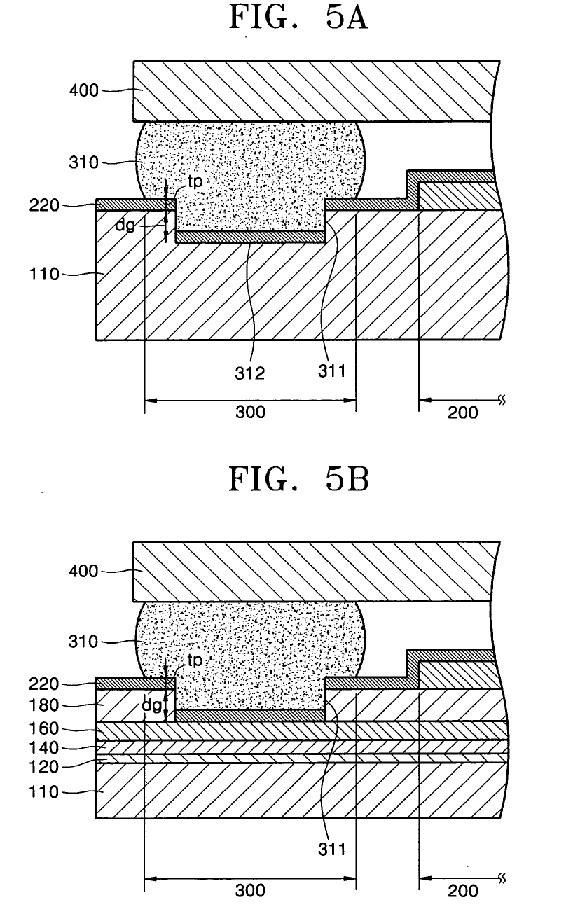

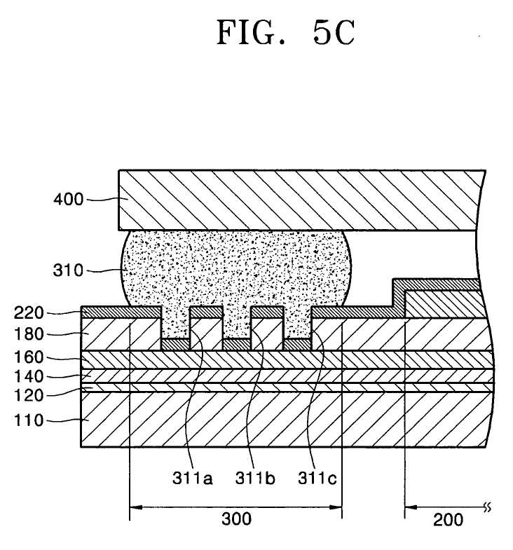

FIG. 5A, FIG. 5B, FIGS. 5C and 5D schematically illustrate partial cross-sections of an organic electro-luminescent display device having a sealing layer, which improves the sealing structure of the display region. FIG. 5A illustrates an organic electro-luminescent display device in which a concave portion 311 is formed in a substrate 110. In this embodiment, a sealing layer 220 covers at least the entire surface of a display region 200 and a part of the sealing layer 220 is placed on at least a bottom surface of the concave portion 311. To more effectively prevent moisture and oxygen from permeating through the interface between the sealing material 310 and the sealing layer 220 and/or through the sealing layer 220, the surface along the route of moisture permeation/oxygen permeation may be discontinuously formed. Referring to FIG. 5A, the sealing layer 220 contacting the sealing material 310 may be discontinuously formed by forming the concave portion 311 in the substrate 110 to a depth dg that is greater than the thickness tp of the sealing layer 220.

FIG. 5B illustrates an organic electro-luminescent display device in which a concave portion 311 extends into one or more insulating layers 120, 140, 160, 180 including a buffer layer formed on a surface of a substrate 110. In this case, a sealing layer 220 covers the entire surface of the display region 200 and is disposed on at least the bottom surface of the concave portion 311. The depth dg of the concave portion 311 may be greater than the thickness tp of the sealing layer 220.

FIG. 5C illustrates an organic electro-luminescent display device in which a concave portion 311 has a repeating recess-protrusion pattern. In this example, the sealing layer 220 covers the entire surface of the display region 200 and is disposed on at least the bottom surface of the concave portion 311, i.e., the bottom surface of the recessed portions 311a, 311b and 311c. The depth dg of the recessed portions 311a, 311b and 311c of the concave portion 311 may be greater than the thickness tp of the sealing layer 220.

Also, the concave portion may be selectively formed in a position corresponding to the sealing portion in at least a part of one or more insulating layers formed on a surface of the substrate. In other words, the concave portion may be selectively formed in a position corresponding to the sealing portion 300 in one or more insulating layers 140, 160 of insulating layers 120, 140, 160, 180 formed on a surface of the substrate 110 as illustrated in FIG. 5C. However, similarly to the organic electro-luminescent display device shown in FIG. 5A, the sealing layer 220 contacting the sealing material 310 may be discontinuously formed by forming the concave portion 311 in the substrate 210 to a greater depth dg than the thickness tp of the sealing layer 220.

The above examples are for illustrative purposes and are not intended to limit the scope of the invention. Although the above examples describe AM organic electro-luminescent display devices, the present invention can also be applied to inorganic electro-luminescent display devices and PM organic electro-luminescent display devices.

In an EL display device manufactured according to the principles of the present invention, the following effects may be obtained. First, the concave portion formed in a sealing portion on a substrate increases the distance that moisture and oxygen must travel to enter a sealing region so that moisture permeation and oxygen permeation are more effectively prevented. This substantially increases the life span of the sealing region and extends longevity of the organic electro-luminescent display device. Second, the concave portion may be formed in a sealing material, thereby increasing a bonding force between the substrate and a sealing substrate. Third, a concave portion may have a repeating recess-protrusion pattern to increase the life span of a sealing and the bonding force between the substrate and the sealing material. Fourth, a concave portion may form a closed curve to efficiently seal a display region. Fifth, a sealing layer may cover the entire surface of a display region to better seal the display region. The depth of a concave portion may be greater than the thickness of the sealing layer to better prevent moisture and oxygen from permeating through the interface between the sealing layer and a sealing material.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An electro-luminescent display device, comprising:
a substrate having a display region;
a sealing portion comprising a sealing material disposed outside the display region; and
a sealing substrate that seals at least the display region in combination with the substrate through the sealing material,
wherein a concave portion is formed in at least part of a position corresponding to the sealing portion at the substrate side.

2. An electro-luminescent display device, comprising:
a substrate having a display region;
a sealing portion comprising a sealing material disposed outside the display region; and
a sealing substrate that seals at least the display region in combination with the substrate through the sealing material,
wherein a concave portion is formed in at least part of the substrate below the sealing portion.

3. The electro-luminescent display device of claim 2, further comprising a sealing layer disposed on the display region and on at least a bottom surface of the concave portion.

4. The electro-luminescent display device of claim 3, wherein a depth of the concave portion is greater than a thickness of the sealing layer.

5. The electro-luminescent display device of claim 2, wherein the concave portion has a repeating recess-protrusion pattern.

6. An electro-luminescent display device, comprising:
a substrate having a display region;
a sealing portion comprising a sealing material disposed outside the display region;
a sealing substrate that seals at least the display region in combination with the substrate through the sealing material; and
one or more insulating layers formed on the substrate,
wherein a concave portion is formed in at least part of the insulating layers below the sealing portion.

7. The electro-luminescent display device of claim 6, further comprising a sealing layer disposed on the display region and on at least the bottom surface of the concave portion.

8. The electro-luminescent display device of claim 7, wherein a depth of the concave portion is greater than a thickness of the sealing layer.

9. The electro-luminescent display device of claim 6, wherein the concave portion has a repeating recess-protrusion pattern.
